(19) United States
(12) Patent Application Publication
(10) Pub. No.: US 2025/0128935 A1
(43) Pub. Date: Apr. 24, 2025

(54) MICROELECTROMECHANICAL SENSING DEVICE AND MANUFACTURING METHOD THEREOF

(71) Applicant: INDUSTRIAL TECHNOLOGY RESEARCH INSTITUTE, Hsinchu (TW)

(72) Inventors: Ming-Fa CHEN, Tainan City (TW); Bor-Shiun LEE, New Taipei City (TW); Chin-Jou KUO, Tainan City (TW)

(73) Assignee: INDUSTRIAL TECHNOLOGY RESEARCH INSTITUTE, Hsinchu (TW)

(21) Appl. No.: 18/920,294

(22) Filed: Oct. 18, 2024

Related U.S. Application Data
(63) Continuation-in-part of application No. 18/528,452, filed on Dec. 4, 2023, now abandoned.

(30) Foreign Application Priority Data
Oct. 20, 2023 (TW) 112140201

(51) Int. Cl. B81B 3/00; B81C 1/00

(52) U.S. Cl. CPC B81B 3/0024; B81C 1/00333; B81B 2201/0278; B81C 2203/0109

(57) ABSTRACT

A microelectromechanical sensing device includes a substrate, a plurality of support structures and a sensing structure. The sensing structure is supported by the plurality of support structures and is disposed above the substrate. The sensing structure includes a first dielectric layer, an electrode layer, a sensing layer and a second dielectric layer. The first dielectric layer has a dielectric top surface coplanar with the support top surface of each of the support structures. The electrode layer is disposed on the first dielectric layer and directly contacts the plurality of support structures. The sensing layer is disposed on the first dielectric layer and a projection of the sensing layer toward the substrate does not overlap the plurality of support structures. The second dielectric layer is disposed on the electrode layer and the sensing layer, wherein the first dielectric layer and the second dielectric layer are made of the same material.

### CROSS-REFERENCE TO RELATED APPLICATIONS

This non-provisional application is a continuation-in-part of U.S. patent application Ser. No. 18/528,452 filed on Dec. 4, 2023, which claims priority under 35 U.S.C. § 119(a) on Patent Application No(s). 112140201 filed in Republic of China (ROC) on Oct. 20, 2023, the entire contents of which are hereby incorporated by reference.

### BACKGROUND

### 1. Technical Field

This disclosure relates to a microelectromechanical sensing device and manufacturing method thereof.

### 2. Related Art

Microelectromechanical sensing device refers to microelectromechanical systems (MEMS) with sensing functions, and operating range and size of the microelectromechanical sensing device are within the micron scale. General sensing elements, such as infrared sensing elements used to measure temperature, often require special support structures (such as anchor points) to be suspended above the substrate to reduce conductive heat dissipation, and require vacuum packaging to reduce heat dissipation through air convection.

### SUMMARY

According to one or more embodiment of this disclosure, a microelectromechanical sensing device includes a substrate, a plurality of support structures and a sensing structure. The plurality of support structures are disposed on the substrate, and each support structure has a support bottom surface and a support top surface respectively located at two opposite ends, and the support bottom surface is connected to the substrate. The sensing structure is supported by the plurality of support structures and is disposed above the substrate. The sensing structure includes a first dielectric layer, an electrode layer, a sensing layer and a second dielectric layer. The first dielectric layer has a dielectric top surface coplanar with the support top surface of each of the plurality of support structures. The electrode layer is disposed on the first dielectric layer and directly contacts the plurality of support structures. The sensing layer is disposed on the first dielectric layer and a projection of the sensing layer toward the substrate does not overlap the plurality of support structures. The second dielectric layer is disposed on the electrode layer and the sensing layer, wherein the first dielectric layer and the second dielectric layer are made of the same material.

According to one or more embodiment of this disclosure, a manufacturing method of a microelectromechanical sensing device includes: forming a sacrificial layer on a substrate; forming a first dielectric layer on the sacrificial layer; embedding a plurality of support structures into the sacrificial layer and the first dielectric layer, such that a support bottom surface of each of the plurality of support structures is connected to the substrate, and making the support top surface of each of the plurality of support structures coplanar with a dielectric top surface of the first dielectric layer, wherein the support bottom surface and the support top surface are respectively located at two opposite ends; forming an electrode layer and a sensing layer on the first dielectric layer, wherein the electrode layer directly contacts the plurality of support structures, and a projection of the sensing layer toward the substrate does not overlap the plurality of support structures; forming a second dielectric layer on the electrode layer and the sensing layer, wherein the second dielectric layer and the first dielectric layer are made of the same material; and making an opening at the first dielectric layer, the electrode layer and the second dielectric layer to release the sacrificial layer.

### BRIEF DESCRIPTION OF THE DRAWINGS

FIG. 1 is a three-dimensional structural diagram of a microelectromechanical sensing device according to an exemplary embodiment of the disclosure;

FIG. 2 is a top view of a microelectromechanical sensing device according to an exemplary embodiment of the disclosure;

FIG. 3 is a schematic cross-sectional view of a microelectromechanical sensing device along a line A-A′ in FIG. 2 according to an exemplary embodiment of the disclosure;

FIG. 4 is a flow chart of a manufacturing method of a microelectromechanical sensing device according to an exemplary embodiment of the disclosure;

FIG. 5 is a schematic diagram of a state of the microelectromechanical sensing device according to steps S1 and S2 in FIG. 4;

FIGS. 6 and 7 are schematic diagrams of a state of the microelectromechanical sensing device according to step S3 in FIG. 4;

FIG. 8 is a schematic diagram of a state of the microelectromechanical sensing device according to steps S4 and S5 in FIG. 4;

FIGS. 9 and 10 are schematic diagrams of a state of the microelectromechanical sensing device according to step S6 in FIG. 4;

FIG. 11 is a structural diagram of a microelectromechanical sensing device according to another exemplary embodiment of the disclosure;

FIGS. 12a to 12e illustrate various implementation aspects of the support structures of the microelectromechanical sensing device of the disclosure;

FIG. 13 is a schematic cross-sectional view of a microelectromechanical sensing device according to another exemplary embodiment of the disclosure;

FIG. 14 is a three-dimensional structural schematic diagram of a microelectromechanical sensing device according to another exemplary embodiment of the disclosure;

FIG. 15 is a flow chart of a manufacturing method of a microelectromechanical sensing device according to another exemplary embodiment of the disclosure;

FIGS. 16 to 20 are schematic diagrams of the states of the microelectromechanical sensing device during the manufacturing process according to steps S6 to S9 in FIG. 15; and

FIG. 21 is a graph of the relationship between a phase angle and the size of a columnar structure of a microelectromechanical sensing device according to another exemplary embodiment of the disclosure.

### DETAILED DESCRIPTION

In the following detailed description, for purposes of explanation, numerous specific details are set forth in order to provide a thorough understanding of the disclosed embodiments. According to the description, claims and the drawings disclosed in the specification, one skilled in the art may easily understand the concepts and features of the present invention. The following embodiments further illustrate various aspects of the present invention, but are not meant to limit the scope of the present invention.

The microelectromechanical sensing device described in one or more embodiments herein may not be limited to specific sensing uses, and an appropriate material layer may be selected as the sensing layer according to different sensing uses, such as temperature sensing, gas sensing, pressure sensing and light sensing, etc.

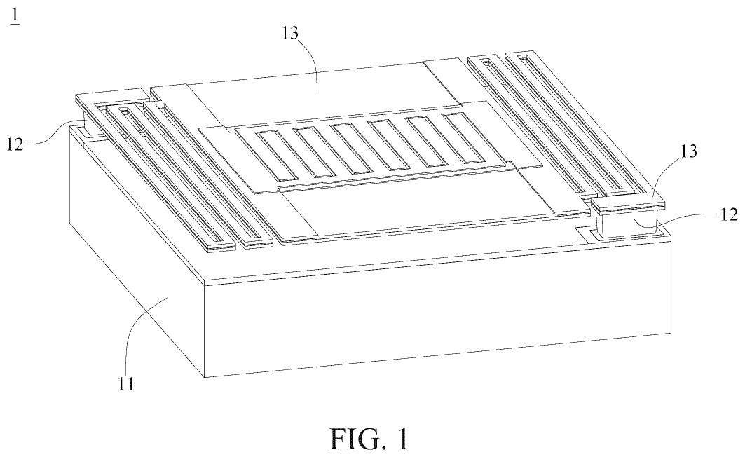

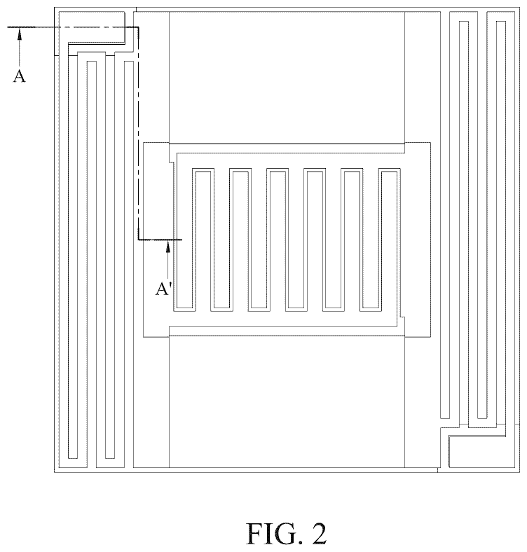

Please refer to FIGS. 1 and 2, FIG. 1 is a three-dimensional structural diagram of a microelectromechanical sensing device according to an exemplary embodiment of the disclosure, FIG. 2 is a top view of a microelectromechanical sensing device according to an exemplary embodiment of the disclosure.

As shown in FIGS. 1 and 2, the microelectromechanical sensing device 1 includes a substrate 11, a plurality of support structures 12 and a sensing structure 13. The substrate 11 may be, but is not limited to, a silicon substrate including a circuit structure (e.g. a readout circuit layer). The plurality of support structures 12 may include two support posts respectively disposed at two diagonal corners of the microelectromechanical sensing device 1, and may be made of a conductive material, such as but not limited to a metal material. The number, location, shape and area of the support posts of the plurality of support structures 12 may be adjusted according to actual applications to stabilize the mechanical structure supporting the sensing structure 13, and are not limited in the disclosure. The sensing structure 13 may be divided into two side areas and a central area. The two side areas of the sensing structure 13 are directly connected to the support structure 12 and have elongated channels, which are mainly used as paths for signal connection and for releasing the sacrificial layer. The central area of the sensing structure 13 is suspended above the substrate 11 and has a sensing layer, which is mainly used to sense environmental changes (such as changes in temperature, gas, pressure, light, etc.) to generate sensing electrical signals. In an embodiment in which the support structure 12 is made of a conductive material, the sensing electrical signal may be transmitted to the readout circuit layer of the substrate 11 through the two side areas of the sensing structure 13 and the support structure 12. Furthermore, a comb-shaped area located in the central area shown in FIG. 1 and FIG. 2 may be the area where the sensing layer is correspondingly provided. It should be noted that FIG. 1 and FIG. 2 only exemplarily illustrate the geometric shape of the sensing structure 13, and the design of the sensing structure 13 may be adjusted according to actual needs.

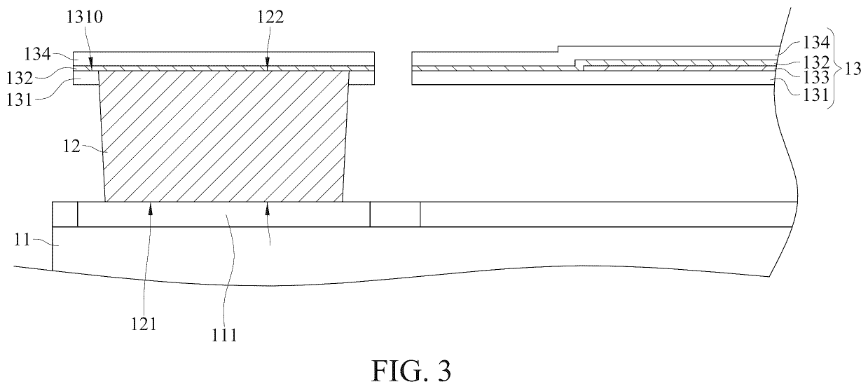

The following description focuses on describing the stacking relationship between the layers of the microelectromechanical sensing device 1 along the direction (normal vector) of the substrate 11. Please refer to FIG. 3 which is a schematic cross-sectional view of a microelectromechanical sensing device along a line A-A′ in FIG. 2 according to an exemplary embodiment of the disclosure.

As shown in FIG. 3, each of the plurality of support structures 12 of the microelectromechanical sensing device 1 is disposed on the substrate 11 and may be a solid post made of a conductive material. Each support structure 12 has a support bottom surface 121 and a support top surface 122 respectively located at two opposite ends, wherein the support bottom surface 121 is connected to the substrate 11. The sensing structure 13 is supported by the support top surface 122 of the support structure 12 and is disposed above the substrate 11. The substrate 11 is, for example, a silicon substrate, and may include a readout circuit layer 111, where the readout circuit layer 111 may include a readout integrated circuit (ROIC). The support structure 12 may be made of a conductive material, especially tungsten metal, so that the support structure 12 may be directly electrically connected to the electrode layer 132 and the readout circuit layer 111. The support structure 12 preferably has a small tilt angle, and is more preferably to be substantially perpendicular to the substrate 11, thereby occupying a small area and making it easy to control the suspension height of the sensing structure 13.

The sensing structure 13 includes a first dielectric layer 131, an electrode layer 132, a sensing layer 133 and a second dielectric layer 134. The first dielectric layer 131 has a dielectric top surface 1310 that is coplanar with the support top surface 122 of the support structure 12. The electrode layer 132 is disposed on the first dielectric layer 131 and directly contacts the support structure 12. The sensing layer 133 is disposed on the first dielectric layer 131 and a projection of the sensing layer 133 toward the substrate 11 does not overlap the plurality of support structures 12. By having two layers of the first dielectric layer 131 and the second dielectric layer 134 of the same material disposed relative to the electrode layer 132 and the sensing layer 133, the sensing structure 13 may have a stress balancing effect, to maintain the uniformity of the overall height of the microelectromechanical sensing device 1. Especially, at the support structure 12, the first dielectric layer 131 and the second dielectric layer 134 are substantially symmetrical with the electrode layer 132 as an axis to provide a better stress balancing effect. It should also be noted that FIG. 3 exemplarily shows that the electrode layer 132 is disposed on the sensing layer 133. However, in other embodiments, the sensing layer 133 may be disposed on the electrode layer 132. That is, the stacking sequence of the electrode layer 132 and the sensing layer 133 is not limited in the disclosure. The second dielectric layer 134 is disposed on the electrode layer 132 and the sensing layer 133, wherein the first dielectric layer 131 and the second dielectric layer 134 are made of the same material.

Furthermore, the first dielectric layer 131 and the second dielectric layer 134 may both be a single material layer or a composite material layer. In an embodiment where the first dielectric layer 131 and the second dielectric layer 134 are implemented by composite material layers, the first dielectric layer 131 includes a plurality of first sub-layers, and the second dielectric layer 134 includes a plurality of second sub-layers. The material composition of the first sub-layers along a stacking direction is the same as the material composition of the second sub-layers along a direction opposite to the stacking direction. The stacking direction may refer to a stacking direction of the first dielectric layer 131, the electrode layer 132 and the second dielectric layer 134. In some embodiments, the first dielectric layer 131 and the second dielectric layer 134 may have the same thickness to form a symmetrical structure.

The material of the sensing structure 13 may be adjusted according to the application. Take the application of infrared light sensing to measure temperature as an example, the first dielectric layer 131 and the second dielectric layer 134 are each an infrared light absorbing layer, and may be composed of silicon dioxide or/and silicon nitride. The material of the electrode layer 132 may be, for example, titanium nitride (TiN). The sensing layer 133 may be made of a material with a resistance value changing with temperature. Through the above structure, the first dielectric layer 131 and the second dielectric layer 134 of the present embodiment absorb the infrared light emitted by the target object and the temperature changes. When the temperature of the sensing layer 133 changes, resistance value of the sensing layer 133 changes accordingly, and the readout circuit layer 111 reads the change in resistance value through the electrode layer 132 and the support structure 12 having a conductive material, and then converts the signal (generated by reading the change in resistance) into the corresponding temperature change to achieve the temperature sensing function.

Preferably, the microelectromechanical sensing device 1 does not include dielectric layers other than the first dielectric layer 131 and the second dielectric layer 134. In addition, the portion of each of the plurality of support structures 12 located between the substrate 11 and the first dielectric layer 131 is preferably not covered with a non-conductive material. Any of the above structural designs may simplify the manufacturing process and improve yield.

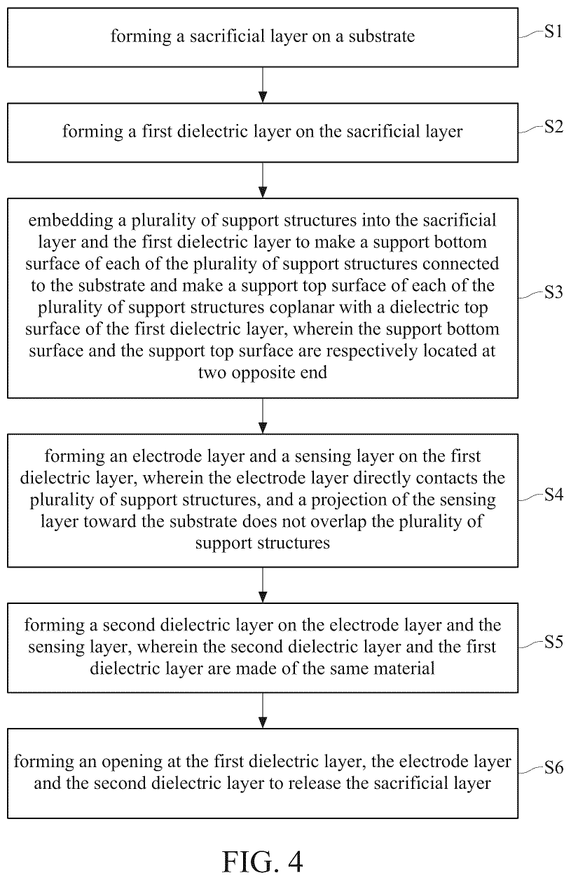

Please refer to FIG. 4 which is a flow chart of a manufacturing method of a microelectromechanical sensing device according to an exemplary embodiment of the disclosure. As shown in FIG. 4, a manufacturing method of a microelectromechanical sensing device includes step S1: forming a sacrificial layer on a substrate; step S2: forming a first dielectric layer on the sacrificial layer; step S3: embedding a plurality of support structures into the sacrificial layer and the first dielectric layer to make a support bottom surface of each of the plurality of support structures connected to the substrate and make a support top surface of each of the plurality of support structures coplanar with a dielectric top surface of the first dielectric layer, wherein the support bottom surface and the support top surface are respectively located at two opposite ends; step S4: forming an electrode layer and a sensing layer on the first dielectric layer, wherein the electrode layer directly contacts the plurality of support structures, and a projection of the sensing layer toward the substrate does not overlap the plurality of support structures; step S5: forming a second dielectric layer on the electrode layer and the sensing layer, wherein the second dielectric layer and the first dielectric layer are made of the same material; and step S6: forming an opening at the first dielectric layer, the electrode layer and the second dielectric layer to release the sacrificial layer.

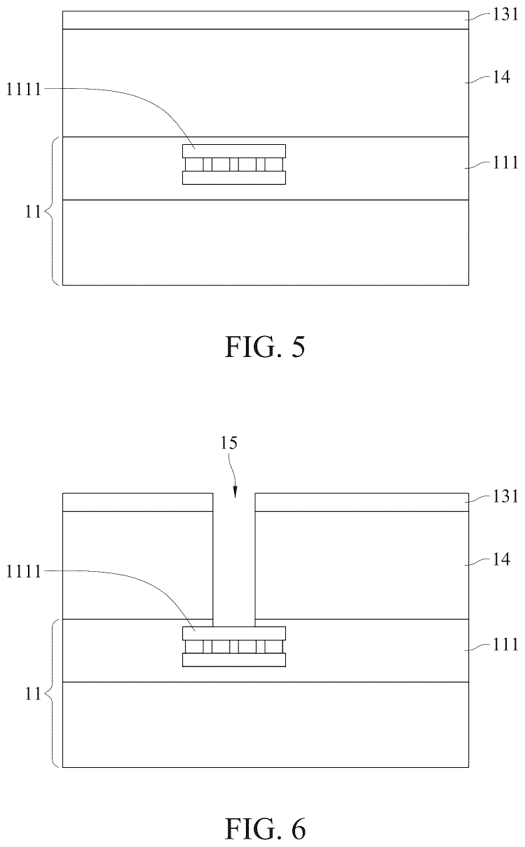

Please refer to FIG. 5 along with FIG. 4, FIG. 5 is a schematic diagram of a state of the microelectromechanical sensing device according to steps S1 and S2 in FIG. 4. In step S1, the substrate 11 including the readout circuit layer 111 may be provided first, and a sacrificial layer 14 may be formed on the readout circuit layer 111 of the substrate 11. The readout circuit layer 111 may be formed on the substrate 11 through a standard complementary metal oxide semiconductor (CMOS) process, and a readout chip 1111 may be disposed in the readout circuit layer 111. The thickness of the sacrificial layer 14 described above may be 1.4 micrometers to 2.5 micrometers. The material of the sacrificial layer 14 may be, for example but not limited to, an amorphous silicon material, and a deposition process may be adopted to form the sacrificial layer 14. In step S2, the first dielectric layer 131 may be formed on the sacrificial layer 14 through a deposition process. In the microelectromechanical sensing device used as an infrared light sensing element, the first dielectric layer 131 may serve as the lower radiation absorbing layer.

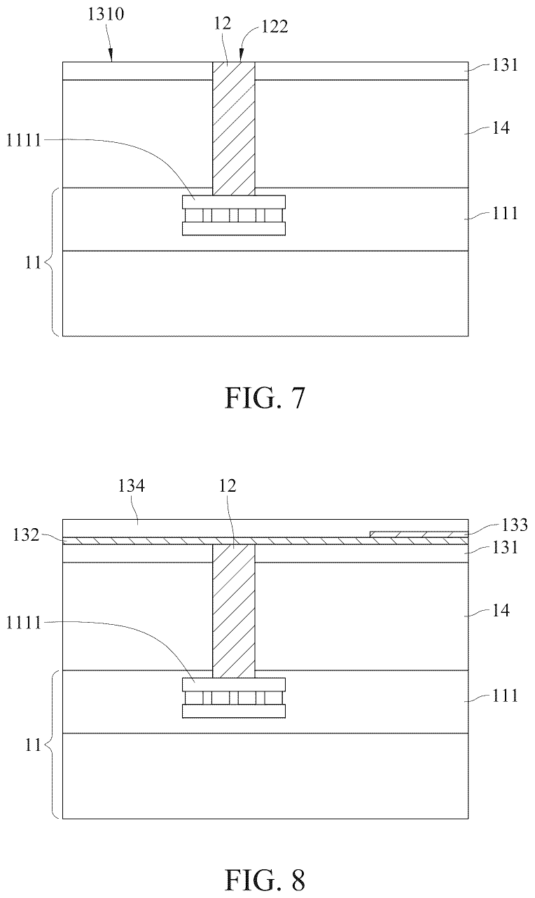

Please refer to FIGS. 6 and 7 along with FIG. 4, wherein FIGS. 6 and 7 are schematic diagrams of a state of the microelectromechanical sensing device according to step S3 in FIG. 4. In step S3, the manufacturing method may include: forming at least one through hole 15 on the sacrificial layer 14 and the first dielectric layer 131; depositing a material in the at least one through hole 15; and using the dielectric top surface 1310 of the first dielectric layer 131 as a stop surface to perform a planarization process to remove part of the material. The through hole 15 described above may be formed through an etching process, wherein the etching process stops at the uppermost layer of the readout chip 1111 of the readout circuit layer 111. The material deposited in the at least one through hole 15 is conductive material. Through step S3, the material of the support structure 12 (especially the conductive material, such as tungsten metal) may be deposited in the through hole 15, so that the support structure 12 is electrically connected to the readout chip 1111 of the readout circuit layer 111 of the substrate 11. A chemical mechanical polishing (CMP) process is performed with the dielectric top surface 1310 of the first dielectric layer 131 as a stop surface to remove excess material, so that the support top surface 122 of the support structure 12 and the dielectric top surface 1310 of the first dielectric layer 131 are coplanar.

Please refer to FIG. 8 along with FIG. 4, FIG. 8 is a schematic diagram of a state of the microelectromechanical sensing device according to steps S4 and S5 in FIG. 4. In step S4, an electrode layer 132 and a sensing layer 133 may be formed on the first dielectric layer 131 and the support structure 12, wherein the electrode layer 132 directly contacts the support structure 12, and a projection of the sensing layer 133 toward the substrate 11 does not overlap the support structure 12. It should be noted that FIG. 8 shows an example where the sensing layer 133 is deposited on the electrode layer 132. However, in other embodiments, the sensing layer 133 may also be deposited on the first dielectric layer 131 and under the electrode layer 132. In step S5, a second dielectric layer 134 may be formed on the electrode layer 132 and the sensing layer 133, wherein the second dielectric layer 134 and the first dielectric layer 131 are made of the same material. It should be noted that although the upper surface of the second dielectric layer 134 in FIG. 8 is shown to be flat, the disclosure is not limited thereto. For example, the second dielectric layer 134 may protrude upward at a location corresponding to the sensing layer 133 to have a higher height. Therefore, the first dielectric layer 131 and the second dielectric layer 134 made of the same material may be used to form a film structure covering the support top surface on the support structure 12, thereby ensuring that the structure is stable and does not deform when suspended. The electrode layer 132 is directly connected to the support structure 12 without additional metal layers.

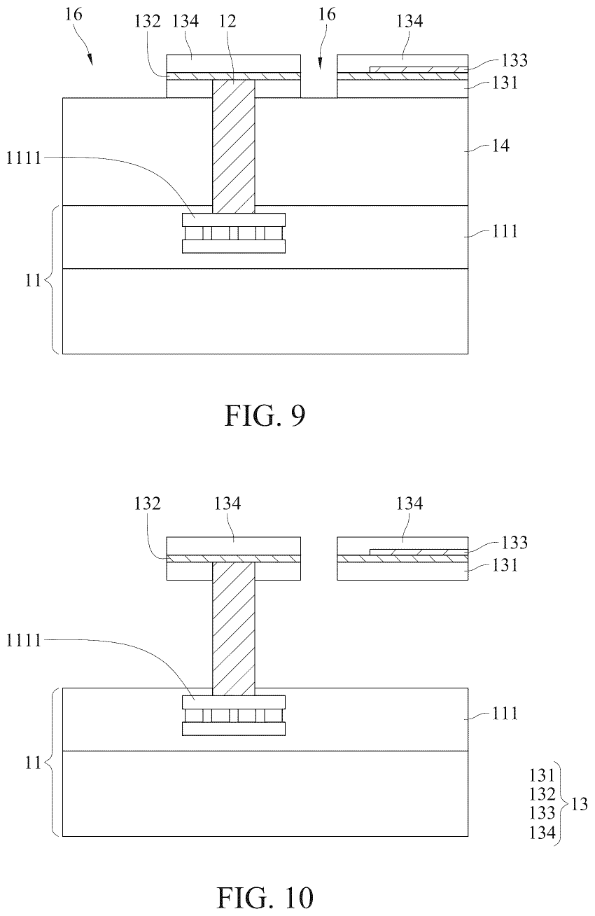

Please refer to FIGS. 9 and 10 along with FIG. 4, FIGS. 9 and 10 are schematic diagrams of a state of the microelectromechanical sensing device according to step S6 in FIG. 4. In step S6, an outline of the infrared light sensing device (microelectromechanical sensing device) may be defined in the first dielectric layer 131, the electrode layer 132 and the second dielectric layer 134 first, including elongated channels, radiation absorption surface, etc., and the first dielectric layer 131, the electrode layer 132 and the second dielectric layer 134 may be etched according to the outline to form openings 16 to form the infrared light sensing device (microelectromechanical sensing device). Then, the sacrificial layer 14 is removed by etching, so that the sensing structure 13 of the infrared light sensing device (microelectromechanical sensing device) is suspended.

Preferably, in the process of the manufacturing method of the microelectromechanical sensing device, the dielectric layer other than the first dielectric layer 131 and the second dielectric layer 134 may not be included to maintain the film structure covering the support top surface, thereby ensuring structural stability and non-deformation during suspension, and simplifying the manufacturing process. In the above process, the first dielectric layer 131 and the second dielectric layer 134 may each be an infrared light absorbing layer, and the sensing layer 133 is made of a material with a resistance value changing with temperature. The support structure 12 is made of a conductive material, specifically tungsten metal, and the support structure 12 is a solid post. The manufacturing method does not include covering the portion of the support structure 12 between the substrate 11 and the first dielectric layer 131 with a non-conductive material.

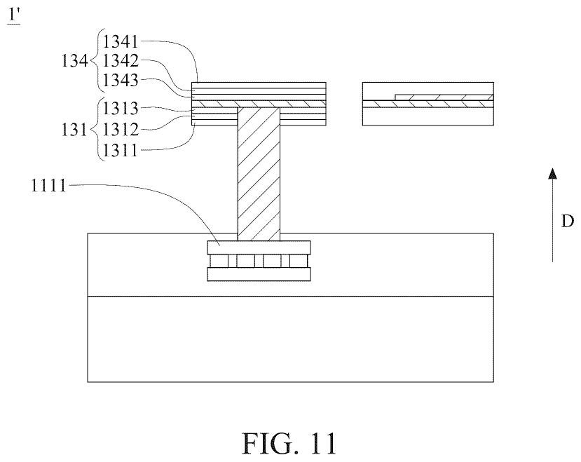

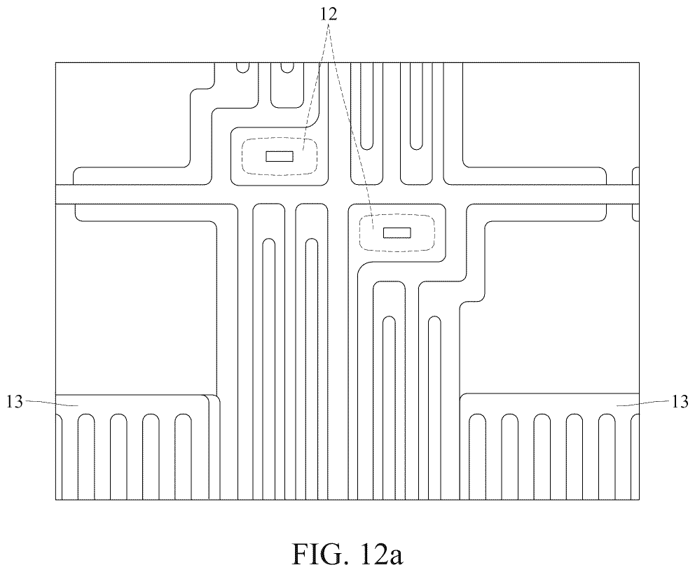

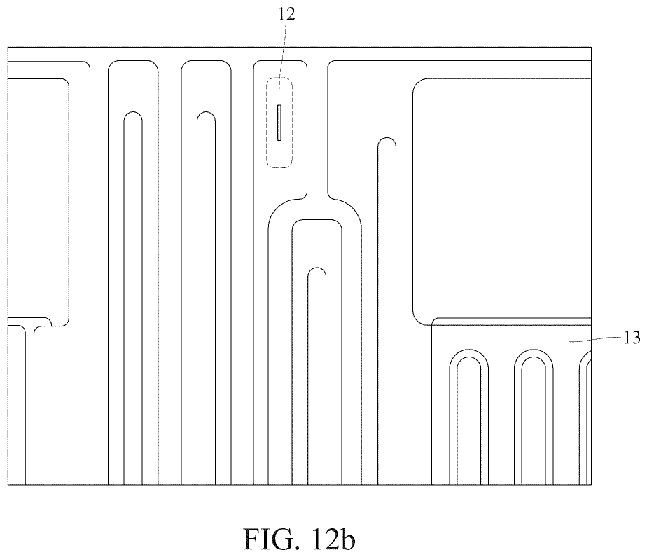

Please refer to FIG. 11 which is a structural diagram of a microelectromechanical sensing device according to another embodiment of the disclosure. As shown in FIG. 11, the first dielectric layer 131 includes a plurality of first sub-layers 1311, 1312 and 1313, and the second dielectric layer 134 includes a plurality of second sub-layers 1341, 1342 and 1343, wherein the material composition of the first sub-layers 1311, 1312 and 1313 along a stacking direction D is the same as the material composition of the second sub-layers 1341, 1342 and 1343 along a direction opposite to the stacking direction D. That is, the first sub-layer 1311 and the second sub-layer 1341 are made of the same material; the first sub-layer 1312 and the second sub-layer 1342 are made of the same material; the first sub-layer 1313 and the second sub-layer 1343 are made of the same material. Specifically, the first sub-layer 1311 and the second sub-layer 1341 may be made of silicon dioxide; the first sub-layer 1312 and the second sub-layer 1342 may be made of silicon nitride; the first sub-layer 1313 and the second sub-layer 1343 may be made of silicon dioxide. Through this composite film layer, the absorption rate of the dielectric layer for infrared light may be improved. In this embodiment, the first sub-layer 1311 and the first sub-layer 1313 are made of the same material (silicon dioxide), and the second sub-layer 1341 and the second sub-layer 1343 are made of the same material (silicon dioxide), but the disclosure is not limited thereto. In addition, in this embodiment, the thickness of the first sub-layer 1311 and the second sub-layer 1341 are approximately the same (e.g., 40 nm); the thickness of the first sub-layer 1312 and the second sub-layer 1342 are approximately the same (e.g., 165 nm); the thickness of the first sub-layer 1313 and the second sub-layer 1343 are approximately the same (e.g., 40 nanometers). This material and thickness symmetrical structure may balance the stress of the composite film layer and keep the sensing structure stable.

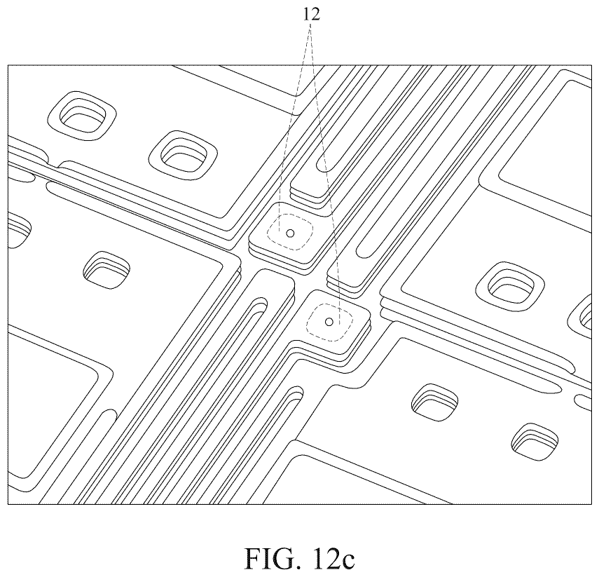

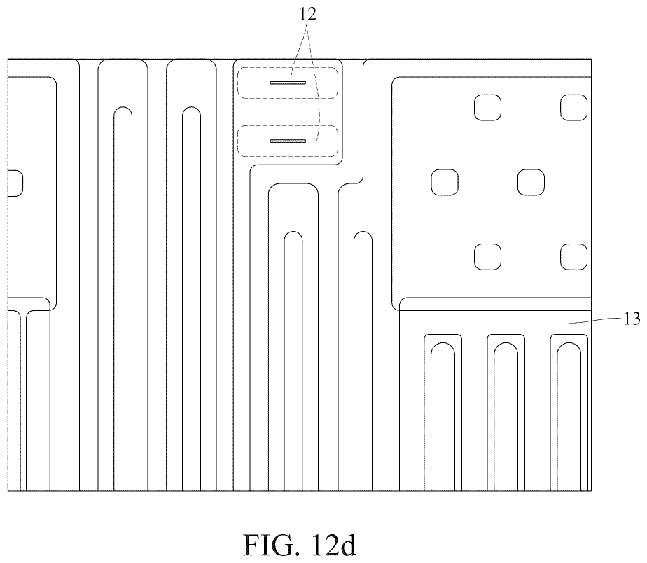

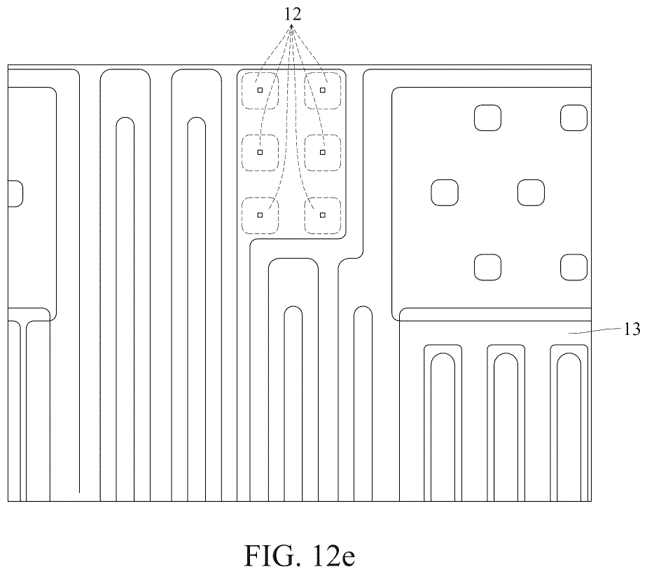

Please refer to FIGS. 12a to 12e, FIGS. 12a to 12e illustrate various implementation aspects of the support structures of the microelectromechanical sensing device of the invention. In this embodiment, the metal posts as the support structure are used in the signal communication to conduct the readout circuit layer connected below and the sensing layer disposed above, for the readout circuit layer to read change of the resistance value. Through the design of planarization and covering structure, the support top surface (upper surface) and radiation absorption surface (upper surface of the second dielectric layer) of the metal post are both flat surfaces (the height difference is less than 2 nanometers), which complies with the CMOS process requirements. The process of the disclosure may avoid structural height differences which may cause uneven film deposition or residues of photoresist, by-products of process, etc. The thin film stack of the process of the disclosure covers the upper ends of the metal post, which also enhances the strength of the suspended structure.

FIG. 12a illustrates a support structure 12 having a metal post with a rectangular cross section arranged along a direction approximately perpendicular to the elongated channels, and a neighboring sensing structure 13. FIG. 12b illustrates a support structure 12 having a metal post with a rectangular cross section arranged along a direction approximately parallel to the elongated channels, and a neighboring sensing structure 13 in the neighbor. FIG. 12c illustrates a support structure 12 having a metal post with a square cross section of small area (1 micron by 1 micron), which is particularly suitable for situation where the overall size of the component is small. FIGS. 12d and 12e illustrate the support structure 12 having multiple metal posts with a rectangular cross section and the neighboring sensing structure 13, wherein the support structure 12 in FIG. 12d includes two metal posts in a corner, and the support structure 12 in FIG. 12e includes six metal posts in a corner. The support structure 12 with the plurality of metal posts is particularly suitable for maintaining overall structure of the component stable under a specific wiring frequency.

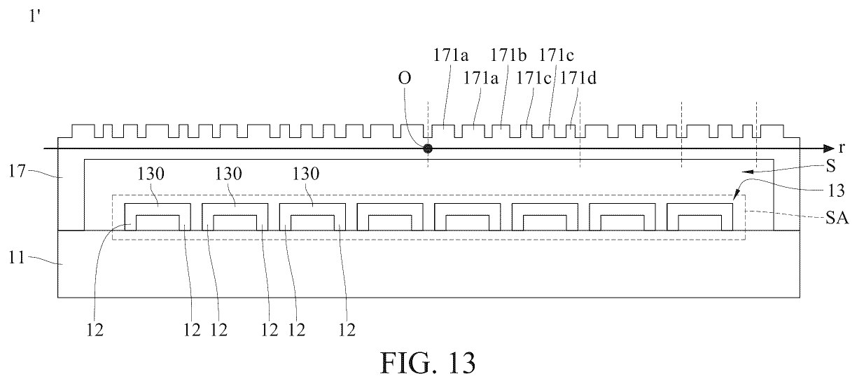

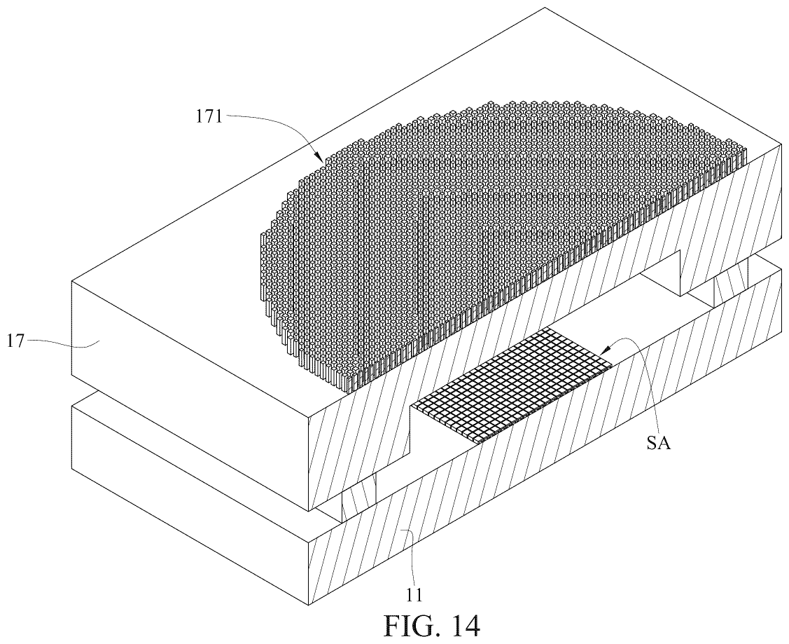

Please refer to FIGS. 13 and 14, wherein FIG. 13 is a schematic cross-sectional view of a microelectromechanical sensing device according to another exemplary embodiment of the disclosure, and FIG. 14 is a three-dimensional structural schematic diagram of a microelectromechanical sensing device according to another exemplary embodiment of the disclosure. As shown in FIG. 13 and FIG. 14, the microelectromechanical sensing device 1′, which includes a substrate 11, a support structure 12, and a sensing structure 13, may further include a package cover 17 that covers a sensing array SA formed by the sensing structure 13 and the support structure 12 together, and is sealed with the substrate 11 to form an accommodating space S therebetween, wherein at least one of an inner surface facing the accommodating space S or an outer surface opposite to the inner surface of the package cover 17 is provided with a plurality of columnar structures 171.

In this embodiment, the sensing structure 13 may be composed of a plurality of sensing units 130 arranged in an array. Each sensing unit 130 includes a portion of the first dielectric layer, a portion of the second dielectric layer, a portion of the electrode layer, and a portion of the sensing layer. The sensing units 130 and the support structure 12 may form the sensing array SA together.

In this embodiment, the structure of the microelectromechanical sensing device 1′ is substantially the same as the structure of the microelectromechanical sensing device 1 in FIG. 1. The material of the package cover 17 may be an infrared-transparent material, such as silicon. The package cover 17 may cover the sensing array SA through a metal bonding method, and form an accommodating space S with the substrate 11. In this example, a plurality of columnar structures 171 are located on an outer surface opposite to the inner surface of the package cover 17. However, in other embodiments, the plurality of columnar structures may be located on the inner surface of the package cover 17, or on both the inner and outer surfaces, which is not limited in the disclosure. The plurality of columnar structures 171 may have different sizes; for instance, the columnar structures 171a, 171b, 171c, and 171d may be periodically arranged along the radial direction of the package cover 17 from wide to narrow in size, but are not limited thereto.

Specifically, the package cover 17 encapsulates the microelectromechanical sensing device F using wafer-level packaging (WLP) technology, and the accommodating space S may be a vacuum space. Thus, by forming a plurality of columnar structures for imaging on the package cover 17 of the wafer-level packaging, packaging and integration of the sensing device and the additional lens group with larger volume may be avoided, achieving the effect of miniaturization the size of the overall microelectromechanical sensing device 1′.

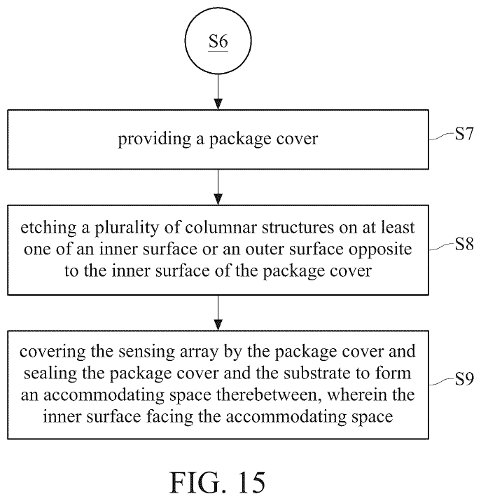

Please refer to FIG. 15, which is a flow chart of a manufacturing method of a microelectromechanical sensing device according to another exemplary embodiment of the disclosure. As shown in FIG. 15, the manufacturing method of the microelectromechanical sensing device after the aforementioned step S6 may further include step S7: providing a package cover; step S8: etching a plurality of columnar structures on at least one of the inner surface of the package cover or the outer surface opposite to the inner surface; and step S9: covering the package cover over the sensing array, and sealing the package cover with the substrate to form an accommodating space therebetween.

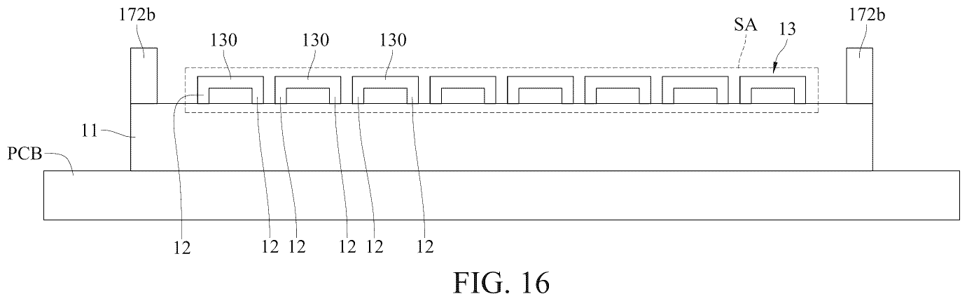

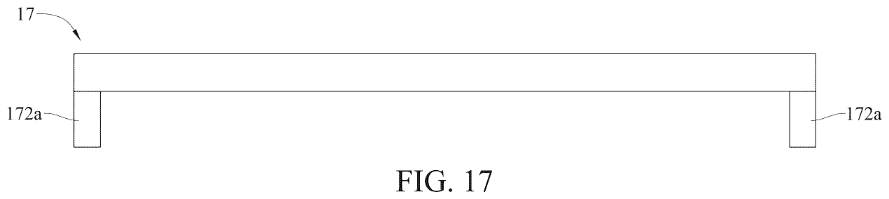

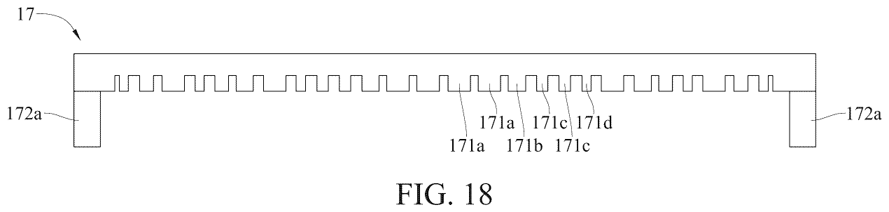

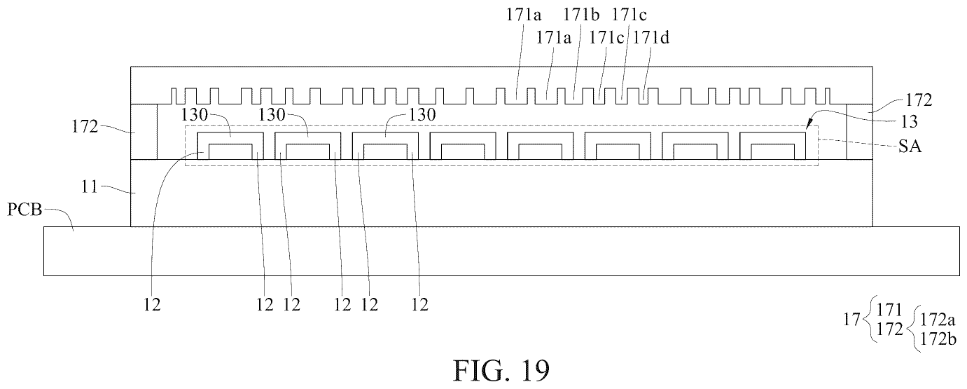

Please refer to FIGS. 16 to 20 in combination with FIG. 15, which are schematic diagrams of the states of the microelectromechanical sensing device during the manufacturing process according to steps S6 to S9 in FIG. 15. As shown in FIG. 16, in step S6, after releasing the sacrificial layer, an unencapsulated portion of the microelectromechanical sensing device F is formed, wherein the plurality of sensing units 130 of the sensing structure 13 form a sensing array. The substrate 11 may be a wafer, and the substrate 11 may be disposed on a printed circuit board PCB. As shown in FIG. 17, in step S7, a package cover 17 may be provided. As shown in FIG. 18, in step S8, a plurality of columnar structures 171 may be etched on at least one of the inner surface or the outer surface opposite to the inner surface of the package cover 17. As shown in FIG. 19, in step S9, the package cover 17 may cover the sensing array, and the package cover 17 and the substrate 11 may be sealed to form an accommodating space therebetween, wherein the inner surface faces the accommodating space. Specifically, the upper cover connection part 172a of the package cover 17 may be bonded to the upper cover connection part 172b on the substrate 11 through a metal bonding method to form a connection part 172 to sealingly form an accommodating space.

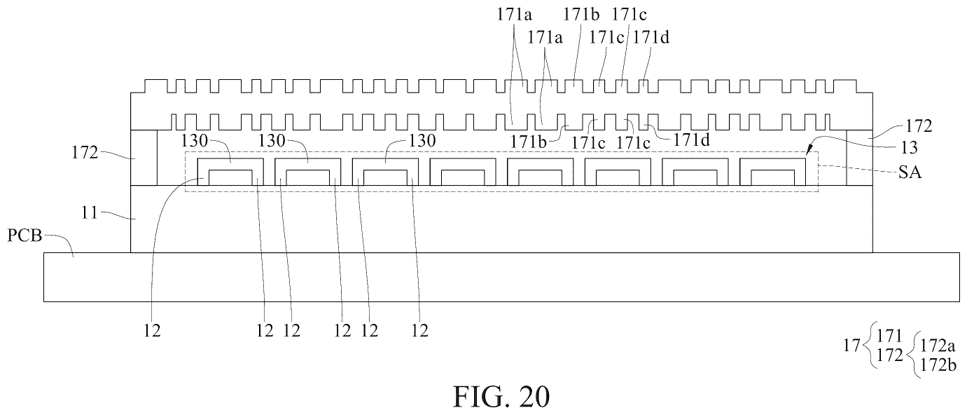

Specially, the execution order of step S8, which involves etching the plurality of columnar structures, and the execution order of step S9, which involves wafer-level packaging, may be interchanged. For example, FIG. 18 illustrates an embodiment where the plurality of columnar structures 171 are formed on the inner surface of the package cover 17, and in this case, etching can be performed before packaging. In another example, if the plurality of columnar structures 171 are to be formed on the outer surface of the package cover 17, packaging can be performed first, followed by etching. Alternatively, as shown in the example in FIG. 20, if the plurality of columnar structures 171 are to be formed on both the inner and outer surfaces of the package cover 17, etching may first be performed on the inner surface, followed by packaging, and then etching on the outer surface.

The aforementioned method of forming columnar structures by etching can be implemented using either dry etching or wet etching, which is not limited in the disclosure. The following description exemplarily outlines the geometric parameters that may be considered in designing the plurality of columnar structures to meet imaging requirements, but is not intended to limit the disclosure. Please refer to equation (1), which describes the formula for the phase difference generated by the columnar structures disposed at various locations on the surface of the package cover on the imaging plane (sensing array). In equation (1), Δφ represents the phase difference, λ represents the wavelength of the incident light, r represents the distance of the columnar structure from the center point, and f represents the imaging focal length of the plurality of columnar structures.

$$Δφ = - \frac{2 π}{λ} ( \sqrt{{r}^{2} + {f}^{2}} - f ) + 2 m π , m = 0 , 1 , 2 … \qquad Equation ( 1 )$$

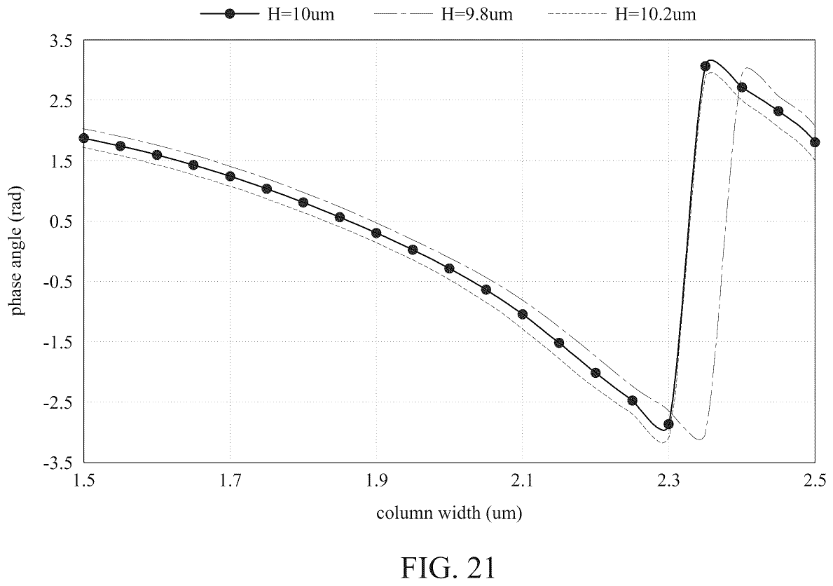

It may be derived from equation (1) that columnar structures located at different positions (with different r) produce different phase differences (Δφ). Furthermore, based on the different phase differences of the columnar structures at these different positions, the geometric dimensions of the columnar structures at different positions may be determined. Please refer to FIG. 21, FIG. 21 is a graph of the relationship between a phase angle and the size of a columnar structure of a microelectromechanical sensing device according to another exemplary embodiment of the disclosure. The graph of FIG. 21 shows the relationship between the column width and the phase angle for the columnar structure in the shape of a “rectangular prism”. In other embodiments, the relationship between the dimensions and the phase angle for columnar structures of other shapes may also be obtained, and the disclosure is not limited thereto. As shown in FIG. 21, FIG. 21 illustrates the relationship between the column width and the phase angle under three different conditions where the column height (H) is 9.8, 10, and 10.2 micrometers, respectively. Based on this graph and equation (1) above, the geometric dimensions of the columnar structures at different positions may be determined, i.e., the size of each of the plurality of columnar structures may be determined according to the imaging focal length (f) and the position (r).

For example, the columnar structures in FIG. 19 include four types of columnar structures 171a, 171b, 171c, and 171d with different column widths, arranged to form a phase difference period ranging from −π to π, and the phase difference period closest to the origin point O is composed of two columnar structures 171a, one columnar structure 171b, two columnar structures 171c, and one columnar structure 171d; the phase difference period that is the second furthest from the origin is composed of one each of columnar structure 171a, columnar structure 171b, columnar structure 171c, and columnar structure 171d; the phase difference period furthest from the origin is composed of one each of columnar structure 171a, columnar structure 171c, and columnar structure 171d; therefore, as the distance from the origin point O increases, the length of a single phase difference period becomes shorter. In other words, the columnar structures are arranged within a narrower range as the distance from the origin point O increases, and the number of columnar structures may be smaller, or there may be fewer types of column widths of columnar structures within the phase difference period. In general, based on equation (1) above, as the columnar structure's position deviates further from the center point (as r increases), the change in the size of the columnar structures becomes more pronounced. In this embodiment, the geometric center of the microelectromechanical sensing device 1′ is taken as the origin point O, but the origin point may be designed at varying positions according to requirements and is not limited to the geometric center.

In view of the above description, the microelectromechanical sensing device of the disclosure is disposed with two dielectric layers of the same material relative to the electrode layer and the sensing layer, the microelectromechanical sensing device may have a stress balancing effect and maintain the uniformity of the overall height. The manufacturing method of the microelectromechanical sensing device of the disclosure may provide a simplified manufacturing process, thereby reducing production difficulties and improving the manufacturing yield of wafers. In addition, by using a support structure made of a metal material and not covered by additional dielectric materials, in addition to support purpose, the support structure may be further used to connect the electrode layer and the readout chip in the substrate to act as a readout signal channel. The dielectric layer formed of composite materials may also increase the infrared light absorption rate. Through the designed planarization process of setting the support top surface of the support structure and the dielectric top surface of the first dielectric layer to be coplanar, the manufacturing method of the microelectromechanical sensing device of the disclosure may reduce production difficulties and improve the manufacturing yield of wafers. The microelectromechanical sensing device of the disclosure and manufacturing method thereof may utilize wafer-level packaging technology for encapsulation, and etch on the surface of the package cover with a plurality of columnar structures to modulate the front phase of the incident light wave and image on the sensing array formed by the sensing structure, without the additional optical lenses. In this way, packaging and integration of the sensing device and the lens group with larger volume may be avoided, thereby achieving the effect of miniaturization the size of the overall optical image sensor.

What is claimed is:

1. A microelectromechanical sensing device, comprising:
a substrate;
a plurality of support structures disposed on the substrate, wherein each of the plurality of support structures has a support bottom surface and a support top surface respectively located at two opposite ends, and the support bottom surface is connected to the substrate;
a sensing structure supported by the plurality of support structures, disposed above the substrate, and comprising:
a first dielectric layer having a dielectric top surface coplanar with the support top surface of each of the plurality of support structures;
an electrode layer disposed on the first dielectric layer and directly contacting the plurality of support structures;
a sensing layer disposed on the first dielectric layer, wherein a projection of the sensing layer toward the substrate does not overlap the plurality of support structures; and
a second dielectric layer disposed on the electrode layer and the sensing layer, wherein the first dielectric layer and the second dielectric layer are made of a same material.

2. The microelectromechanical sensing device of claim 1, wherein the first dielectric layer comprises a plurality of first sub-layers, the second dielectric layer comprises a plurality of second sub-layers, and a material composition of the plurality of first sub-layers along a stacking direction is the same as a material composition of the plurality of second sub-layers along a direction opposite to the stacking direction.

3. The microelectromechanical sensing device of claim 1, not comprising a dielectric layer other than the first dielectric layer and the second dielectric layer.

4. The microelectromechanical sensing device of claim 1, wherein the first dielectric layer and the second dielectric layer are each an infrared light absorbing layer, and the sensing layer is made of a material with a resistance value changing with temperature.

5. The microelectromechanical sensing device of claim 1, wherein the plurality of support structures are made of a conductive material, and are electrically connected to the electrode layer.

6. The microelectromechanical sensing device of claim 1, wherein each of the plurality of support structures is a solid post made of a conductive material, and a portion of each of the plurality of support structures located between the substrate and the first dielectric layer is not covered with a non-conductive material.

7. The microelectromechanical sensing device of claim 1, wherein the sensing structure and the plurality of support structures form a sensing array, and the microelectromechanical sensing device further comprises:
a package cover covering the sensing array and sealed with the substrate to form an accommodating space therebetween,
wherein at least one of an inner surface facing the accommodating space or an outer surface opposite to the inner surface of the package cover is provided with a plurality of columnar structures.

8. The microelectromechanical sensing device of claim 7, wherein the accommodating space is a vacuum space.

9. The microelectromechanical sensing device of claim 7, wherein the plurality of columnar structures has a focal length, each of the plurality of columnar structures has a position, and a size of each of the plurality of columnar structures is determined by the focal length and the position.

10. The microelectromechanical sensing device of claim 7, wherein both the inner surface and the outer surface of the package cover are provided with the plurality of columnar structures.

11. A manufacturing method of a microelectromechanical sensing device, comprising:
forming a sacrificial layer on a substrate;
forming a first dielectric layer on the sacrificial layer;
embedding a plurality of support structures into the sacrificial layer and the first dielectric layer to make a support bottom surface of each of the plurality of support structures connected to the substrate and make a support top surface of each of the plurality of support structures coplanar with a dielectric top surface of the first dielectric layer, wherein the support bottom surface and the support top surface are respectively located at two opposite ends;
forming an electrode layer and a sensing layer on the first dielectric layer, wherein the electrode layer directly contacts the plurality of support structures, and a projection of the sensing layer toward the substrate does not overlap the plurality of support structures;
forming a second dielectric layer on the electrode layer and the sensing layer, wherein the second dielectric layer and the first dielectric layer are made of a same material; and
forming an opening at the first dielectric layer, the electrode layer and the second dielectric layer to release the sacrificial layer.

12. The manufacturing method of the microelectromechanical sensing device of claim 11, wherein embedding the plurality of support structures into the sacrificial layer and the first dielectric layer to make the support bottom surface of each of the plurality of support structures connected to the substrate and make the support top surface of each of the plurality of support structures coplanar with the dielectric top surface of the first dielectric layer comprises:
forming at least one through hole in the sacrificial layer and the first dielectric layer;
depositing a material in the at least one through hole; and
using the dielectric top surface of the first dielectric layer as a stop surface to perform a planarization process to remove part of the material.

13. The manufacturing method of the microelectromechanical sensing device of claim 11, wherein forming the first dielectric layer on the sacrificial layer comprises:
forming a plurality of first sub-layers on the sacrificial layer along a stacking direction,
wherein forming the second dielectric layer on the electrode layer and the sensing layer comprises:
forming a plurality of second sub-layers on the electrode layer and the sensing layer along the stacking direction,
wherein a material composition of the plurality of first sub-layers along the stacking direction is the same as a material composition of the plurality of second sub-layers along a direction opposite to the stacking direction.

14. The manufacturing method of the microelectromechanical sensing device of claim 11, not comprising forming a dielectric layer other than the first dielectric layer and the second dielectric layer.

15. The manufacturing method of the microelectromechanical sensing device of claim 11, wherein the first dielectric layer and the second dielectric layer are each an infrared light absorbing layer, and the sensing layer is made of a material with a resistance value changing with temperature.

16. The manufacturing method of the microelectromechanical sensing device of claim 11, the plurality of support structures are made of a conductive material.

17. The manufacturing method of the microelectromechanical sensing device of claim 11, wherein each of the plurality of support structures is a solid post made of a conductive material, and the manufacturing method of the microelectromechanical sensing device does not comprise covering a portion of each of the plurality of support structures located between the substrate and the first dielectric layer with a non-conductive material.

18. The manufacturing method of the microelectromechanical sensing device of claim 11, further comprising:
providing a package cover;
etching a plurality of columnar structures on at least one of an inner surface or an outer surface opposite to the inner surface of the package cover; and
covering a sensing array by the package cover and sealing the package cover and the substrate to form an accommodating space therebetween, wherein the inner surface facing the accommodating space.

19. The manufacturing method of the microelectromechanical sensing device of claim 18, wherein the plurality of columnar structures has a focal length, each of the plurality of columnar structures has a position, and a size of each of the plurality of columnar structures is determined by the focal length and the position.

20. The manufacturing method of the microelectromechanical sensing device of claim 18, wherein the accommodating space is a vacuum space.
